(19) United States
(12) Patent Application Publication
(10) Pub. No.: US 2016/0013565 A1
(43) Pub. Date: Jan. 14, 2016

(54) MULTI-BAND ANTENNA ASSEMBLY

(71) Applicant: Mueller International, LLC, Atlanta, GA (US)

(72) Inventor: Jorge Isaac Ortiz, Ocala, FL (US)

(21) Appl. No.: 14/331,196

(22) Filed: Jul. 14, 2014

(51) Int. Cl. H01Q 21/30; H05K 1/18; H01Q 21/00; H01Q 1/52

(52) U.S. Cl. CPC H01Q 21/30; H01Q 1/526; H05K 1/18; H01Q 21/0087; H05K 2201/10098; H05K 2201/09027

(57) ABSTRACT

Antenna assemblies and methods of manufacturing antenna assemblies are provided. In one embodiment, an antenna assembly comprises a printed circuit board having a first surface and a second surface. The antenna assembly also includes a cellular antenna structure having a first section disposed on the first surface of the printed circuit board and a second section disposed on the second surface of the printed circuit board. The antenna assembly further includes a wireless local area antenna structure having a first section disposed on the first surface of the printed circuit board and a second section disposed on the second surface of the printed circuit board.

### TECHNICAL FIELD

The present disclosure generally relates to radio frequency (RF) and microwave frequency communication, and more particularly relates to antenna assemblies operating at RF or microwave frequencies.

### BACKGROUND

Wireless communication technology has advanced significantly over the past several years. A non-exhaustive list of examples of wireless communication systems includes radio broadcasting, television broadcasting, satellite television, two-way radio devices (e.g., CB radio, amateur radio, etc.), cellular phones, cordless phones, wireless local area networking, global positioning system (GPS) receivers, garage door openers, television remote control devices, and others. Each type of wireless communication system operates in specific frequency bands in compliance with various communication standards.

Some wireless communication devices are able to operate over two or more frequency bands to provide multiple services. However, many wireless devices operating in multiple bands include a single antenna, such that only one service can be provided at a time. Usually, conventional multi-band antennas are large and bulky, which prevents their application in many settings. Also, conventional multi-band antennas typically have a lower-than-average gain.

An issue regarding radio frequency (RF) and microwave frequency communication is the occurrence of reflection signals when input or output communications signals encounter discontinuities or mismatches in the waveguide path. A solution to this problem is to incorporate an impedance matching circuit at the discontinuities to minimize reflections. However, many impedance matching circuits are designed before the communication circuitry is installed in the environment where it is intended to operate. Since the environment has an effect on the electrical characteristics of communication circuitry, the matching circuit designed in an ideal setting may be inadequate once it is installed in its actual operating environment. This may result in a loss in the performance of the communication circuitry.

### SUMMARY

The present disclosure relates generally to antenna assemblies. In one implementation, an antenna assembly according to the teachings of the present disclosure may comprise a printed circuit board having a first surface and a second surface. A cellular antenna structure of the antenna assembly may have a first section disposed on the first surface of the printed circuit board and a second section disposed on the second surface of the printed circuit board. A wireless local area antenna structure of the antenna assembly may have a first section disposed on the first surface of the printed circuit board and a second section disposed on the second surface of the printed circuit board.

The present disclosure also describes methods of manufacturing an antenna assembly. In one implementation, a method of manufacturing may include the step of fabricating a printed circuit board with a ground layer, a plurality of microstrip segments, and an aperture, the microstrip segments forming at least a first antenna and a second antenna. The method may also include installing a global positioning system (GPS) module in the aperture of the printed circuit board and coupling a terminal of the GPS module with the ground layer of the printed circuit board.

Furthermore, the present disclosure also describes printed circuit boards. In one implementation, a printed circuit board (PCB) may comprise a first antenna structure configured to operate in a radio frequency (RF) band and a second antenna structure configured to operate in a microwave frequency band, wherein the frequencies of the RF and microwave frequency bands are separate. The PCB may also comprise an aperture configured to accommodate a global positioning system (GPS) module.

Various implementations described in the present disclosure may include additional systems, methods, features, and advantages, which may not necessarily be expressly disclosed herein but will be apparent to one of ordinary skill in the art upon examination of the following detailed description and accompanying drawings. It is intended that all such systems, methods, features, and advantages be included within the present disclosure and protected by the accompanying claims.

### BRIEF DESCRIPTION OF THE DRAWINGS

The features and components of the following figures are illustrated to emphasize the general principles of the present disclosure. Corresponding features and components throughout the figures may be designated by matching reference characters for the sake of consistency and clarity.

FIG. 1 is a diagram showing a first side of an antenna assembly, according to various embodiments of the present disclosure.

FIG. 2 is a diagram showing a second side of the antenna assembly of FIG. 1, according to various embodiments of the present disclosure.

FIG. 3 is a diagram showing the first side of the antenna assembly of FIG. 1 with the elements of the second side shown in phantom.

FIGS. 4-6 are screen shots of a user interface showing test results using an electromagnetic field scanner to test a prototype of the antenna assembly of FIG. 1, according to various embodiments of the present disclosure.

FIG. 7 is a table showing test results of effective isotropic radiated power (EIRP) of a prototype of the antenna assembly of FIG. 1.

FIGS. 8-14 are screen shots of a signal analyzer showing test results of a prototype of the antenna assembly of FIG. 1, according to various embodiments of the present disclosure.

### DETAILED DESCRIPTION

The present disclosure describes antenna assemblies and methods of manufacturing antenna assemblies, particularly antenna assemblies designed to operate in the radio frequency (RF) and/or microwave frequency ranges. Microstrip technology can be used for forming antenna assemblies on a printed circuit board (PCB). Instead of designing antenna assemblies with respect to operation in an ideal setting, as is typically the case in conventional design operations, the present disclosure describes antenna assemblies that operate with minimal loss after being installed in their intended operating environment. For example, an antenna assembly may be installed near a metal frame (e.g., a metal valve cover of a water distribution system), at various location, such as near or below ground level (e.g., within a fire hydrant or water conduit), or in other environments where communication signals may be significantly affected.

Also, the present disclosure describes antenna assemblies that include two or more antennas. In some embodiments, the multiple antennas can be contained on a single medium, such as on a printed circuit board (PCB). Furthermore, the multiple antennas can be designed to operate in different frequency ranges to allow multiple types of services. An antenna assembly having multiple antennas operating in multiple frequency bands can be referred to as a “multi-band antenna assembly.” Multi-band antenna assemblies can also be formed on a single PCB to allow communication in multiple frequency ranges.

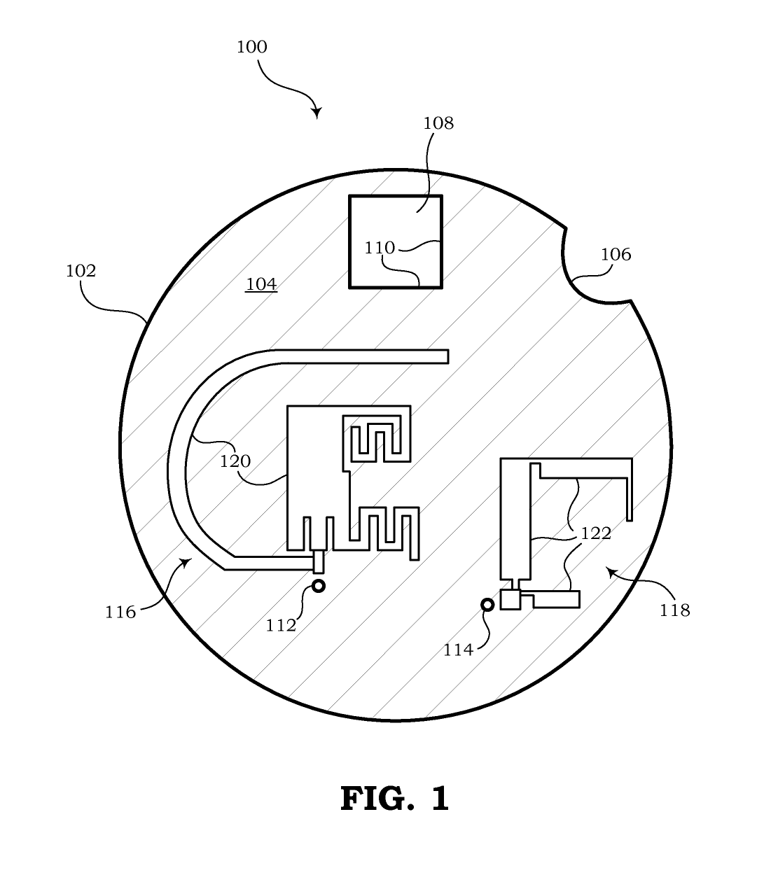

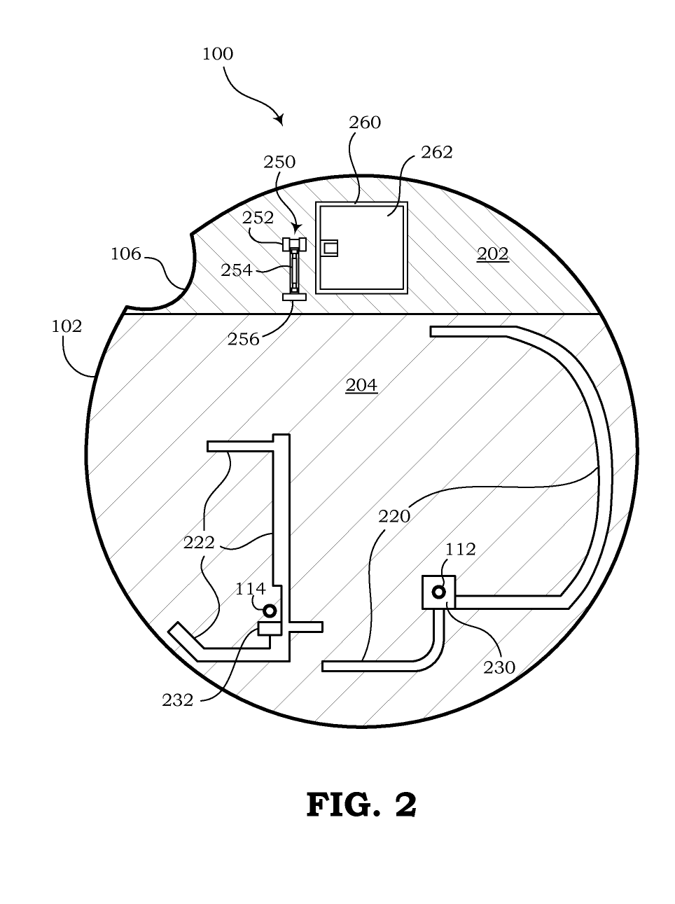

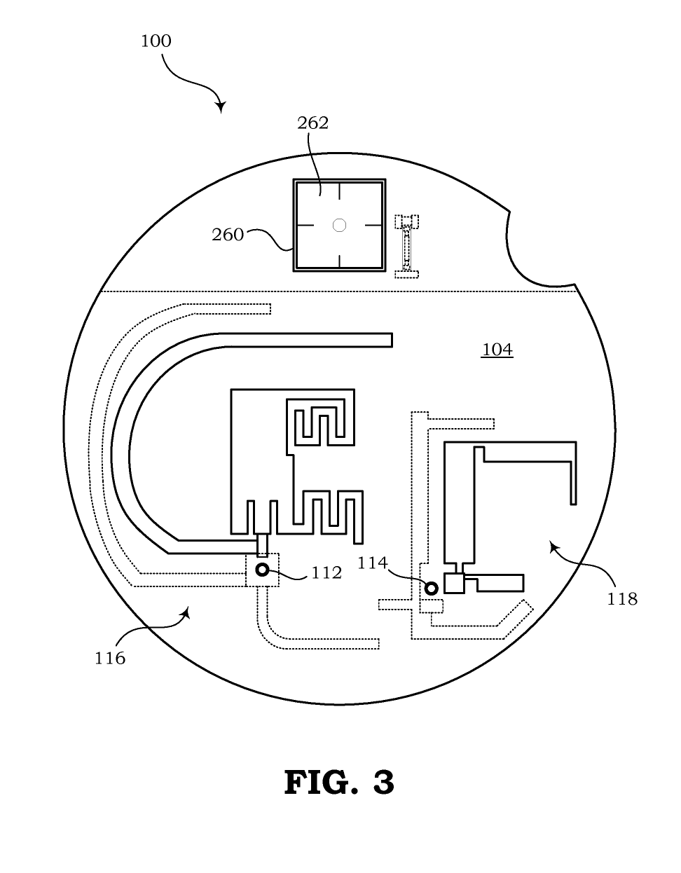

FIGS. 1-3 show top and bottom views of an embodiment of an antenna assembly 100 according to various implementations of the present invention. FIG. 1 shows a top view of the antenna assembly 100; FIG. 2 shows a bottom view of the antenna assembly 100; and FIG. 3 shows the features on a top surface 104 of a printed circuit board 102 of the antenna assembly 100 with the features on a bottom surface 204 of the printed circuit board 102 shown in phantom. The top surface 104 of the printed circuit board 102 is shown in FIGS. 1 and 3 and the bottom surface 204 is shown in FIG. 2. The printed circuit board 102 includes a notch 106 that allows the printed circuit board 102 to be aligned properly in a particular environment in which it is installed. The printed circuit board 102 also includes an aperture 108 configured to accommodate a global positioning system (GPS) module 262 (FIGS. 2 and 3). Edges 110 of the aperture 108 are configured to engage the GPS module 262 or a receptacle connector 260 configured to support the GPS module 262.

According to some embodiments, the printed circuit board 102 may comprise a flame retardant composite material of glass epoxy resin, such as FR-4. The printed circuit board 102 may have the shape of a disk, as shown, or any other suitable shape based on the environment in which it is intended to be installed. In particular, the printed circuit board 102 may be substantially circular with a diameter of 4.55 inches and a thickness of 0.030 inches, which would allow the printed circuit board 102 to be installed in a valve cover of a water distribution system.

The antenna assembly 100 further includes two layers of copper laminate, one layer etched on the top surface 104 of the printed circuit board 102 and the other layer etched on the bottom surface 204. The layers are etched to create two distinct antenna structures—a first antenna structure 116 and a second antenna structure 118. Each of the antenna structures 116, 118 includes two sections, where one section of the respective antenna structure is formed on the top surface 104 of the printed circuit board 102 and the other section of the respective antenna structure is formed on the bottom surface 204 of the printed circuit board 102. The antenna structures 116 and 118 are formed as microstrip segments to achieve the desired impedance, capacitance, and inductance characteristics of the antenna circuitry.

The first antenna structure 116 includes a first section 120 formed on the top surface 104 and a second section 220 formed on the bottom surface 204. The second antenna structure 118 includes a first section 122 formed on the top surface 104 and a second section 222 formed on the bottom surface 204. The first section 120 and second section 220 of the first antenna structure 116 are coupled to each other via a first through-hole 112. The first section 122 and second section 222 of the second antenna structure 118 are coupled to each other via the second through-hole 114. As shown in FIG. 2, the first through-hole 112 is coupled to a first solder pad 230 and the second through-hole 114 can be coupled to a second solder pad 232.

The first antenna structure 116 is configured to operate in a wideband frequency range for cellular communication. For example, the first antenna structure 116 is capable of operating in a range from about 600 MHz to over 6 GHz. Therefore, the first antenna structure 116 is able to cover at least seven cellular bands of 700, 800, 900, 1700, 1800, 1900, and 2000 MHz, as well as additional cellular bands between 2 GHz and 6 GHz that may be developed in the future. According to test results, while achieving a return loss (S11) of less than −7 dBm, the bandwidth of the first antenna structure 116 was over 400 MHz between 600 MHz and 1 GHz and was over 2900 MHz between 1.7 GHz and 5 GHz. The voltage standing wave ration (VSWR) ranged from a minimum of less than 1.0 to about 2.0 at the operating cellular bands. Based on these tests, the estimated efficiency was measured at over 72% between 600 MHz and 2 GHz and over 85% between 2 GHz and 6 GHz.

The first section 120 of the first antenna structure 116 includes one long strip and two serpentine strips. The second section 220 of the first antenna structure 116 includes a short strip and a long strip. As shown in FIG. 3, the long strip of the first section 120 and the long strip of the second section 220 are substantially parallel. It should be noted that the microstrip segments of the first section 120 and the microstrip segments of the second section 220 are not located opposite of each other on the PCB 102 but are offset by a predetermined distance.

The second antenna structure 118 is configured to operate in a wideband frequency range for wireless local area communication (e.g., WiFi™ communication). For example, the second antenna structure 118 is capable of operating in a range from about 2 GHz to 5 GHz. Therefore, the second antenna structure 118 is able to cover at least two wireless local area frequency bands of 2 GHz and 5 GHz, as well as an additional band (e.g., 3 GHz) that may be developed in the future. According to test results, while achieving a return loss (S11) of less than −7 dBm, the bandwidth of the second antenna structure 118 was over 400 MHz at 2.4 GHz was over 200 MHz at 3.6 GHz (possible future Wi-Fi band), and was over 500 MHz at 5.0 GHz.

The first section 122 of the second antenna structure 118 includes a combination of wide and thin microstrip segments. The second section 222 of the second antenna structure 118 includes a combination of medium width strips. As shown in FIG. 3, the microstrip segments of the first section 122 and the microstrip segments of the second section 222 are not located opposite of each other on the PCB 102 but are offset by a predetermined distance.

The first solder pad 230 is configured to be soldered to a first cable (not shown), such as a 0.81 mm coaxial cable. The other end of the first cable may include a Murata GSC connector or other similar connector configured to be connected to a cellular transceiver. The second solder pad 232 is configured to be soldered to a second cable (not shown), such as a 0.81 mm coaxial cable. The other end of the second cable may include a Murata GSC connector or other similar connector configured to be connected to a wireless local area transceiver, such as a Wi-Fi transceiver. The cellular transceiver and wireless local area transceiver may be mounted on the PCB 102 or on a separate board in proximity to the PCB 102. According to other embodiments, the solder pads 230 and 232 may be replaced with receptacle connectors mounted on the bottom surface 204 of the PCB 102. The receptacle connectors may be able to accommodate the cellular transceiver and wireless local area transceiver directly without the solder pads 230, 232 and corresponding cables. Although the receptacle connectors may come with a higher cost, these elements would consequently provide a lower profile antenna assembly.

As shown in particular in FIG. 2, a ground layer 202 is formed on the bottom surface 204 of the PCB 102. The ground layer 202 may be configured to surround the aperture 108. A receptacle connector 260 (e.g., an IPEX MHF type connector) is coupled to the edges 110 of the aperture 108. The GPS module 262 (such as an off-the-shelf GPS device) is inserted in the receptacle connector 260. The ground layer 202 is configured to minimize interference on the first and second antenna structures 116, 118 resulting from a low noise amplifier (LNA) of the GPS module 262. The ground layer 202 is also configured to reduce multipath effects on the GPS module 262 itself. Additionally, a termination device 250 is formed on the ground layer 202. The termination device 250 includes a connector 252, a coaxial cable 254 (e.g., a 0.81 mm coaxial cable), and an end terminal 256. The GPS module 262 may include a cable (not shown) that extends from the body of the GPS module 262 and is connected to the connector 252. For example, the connector 252 may be a Murata GSC connector, an SMT MHF connector, or other suitable connector. The end terminal 256 is configured to be soldered to the ground layer 202 on the bottom surface 204 of the PCB 102.

Although the first antenna structure 116, second antenna structure 118, and GPS module 262 are collocated on the same printed circuit board 102, they are configured to operate simultaneously with minimal interference among themselves. Even though the antenna structures 116, 118 are relatively flat, they are configured to exhibit omni-directional transmission and reception patterns. The low profile of the antenna assembly 100 allows the antenna assembly 100 to be installed in certain environments where space may be an issue (e.g., where a typical monopole or protruding antenna may not be acceptable).

For example, the antenna assembly 100 may be installed within a water distribution system, such as in a fire hydrant at ground level or in a valve cover below ground level. The antenna assembly 100 may also be installed on a vehicle or in other environments where cellular communication, wireless local area communication, and GPS communication are desired. Furthermore, the antenna structures 116, 118 are configured to operate effectively in practically any environment, allowing installation in ground level and even below-ground level environments.

Impedance matching is obtained by the antenna assembly 100 of the present disclosure based on a combination of the microstrip patterns of each of the first and second antenna structures 116, 118, the effects of the antenna structures 116, 118 and GPS module 262 on each other, the effects of a valve cover in proximity to the assembly, and potting material used to physically support the elements of the antenna. The microstrip segments of the first and second antenna structures 116, 118 provide electrical properties that when combined with the environmental elements provide RF and microwave frequency communication characteristics to enable high gain communication. The specific design of the microstrip elements of each segment of the antenna structures 116, 118 and the specific location of the antenna structure 116, 118 with respect to each other and with respect to the ground layer 202 and GPS module 262 enable the antenna assembly 100 to exhibit a very high bandwidth and operate at low and high power levels, though various designs and locations may be present in various other embodiments.

A prototype of the antenna assembly 100 described above has been built and has been exposed to near-field and far-field testing. Some tests have been performed with the antenna assembly 100 mounted on a cover assembly and metal sleeve for simulating an environment of a valve cover of a water distribution system. Signals at various frequencies were applied to the antenna assembly 100 using a signal generator at 15 dBm. An electromagnetic field scanner was used to obtain transmission and reception properties of the antenna assembly 100. Results were displayed on an antenna design tool in real time to produce 3D graphics of the electromagnetic near-field test as well as far-field propagation prediction based on near-field formation test results.

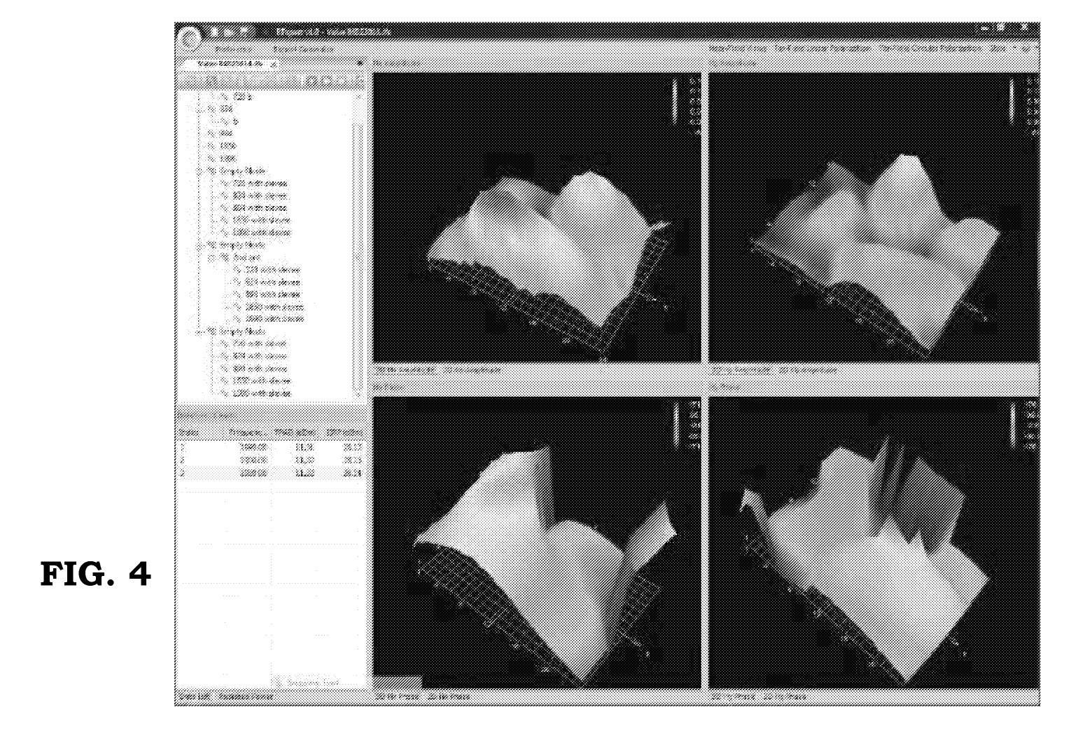

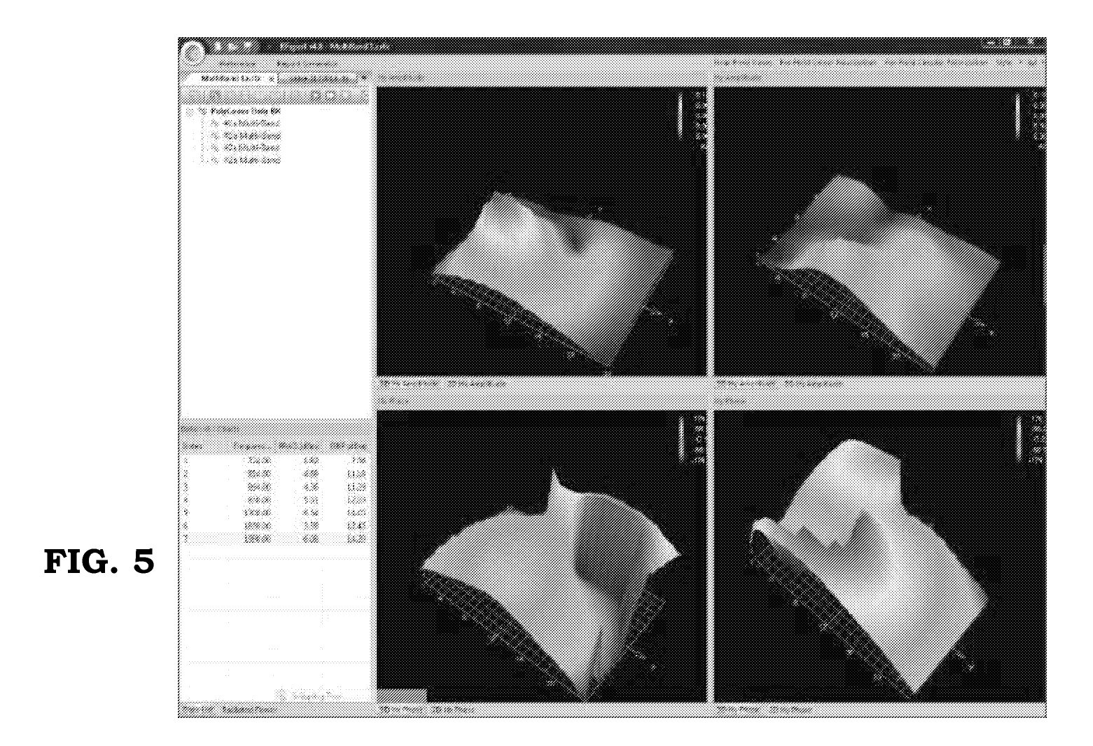

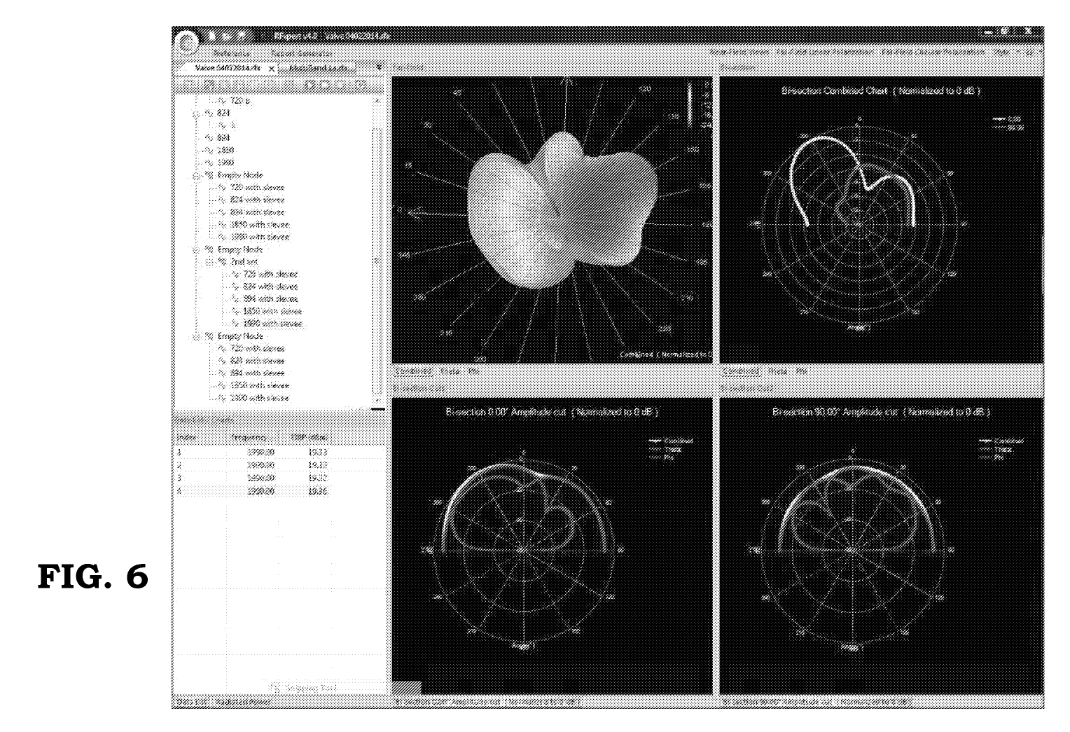

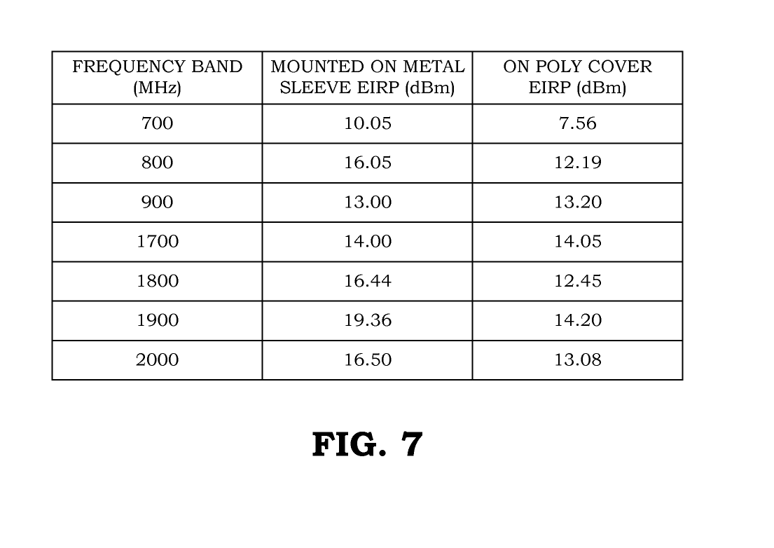

FIG. 4 shows electromagnetic near-field test results at 1990 MHz when the antenna assembly 100 was inserted in a metal sleeve. FIG. 5 shows electromagnetic near-field test results at 1990 MHz without a metal sleeve. FIG. 6 shows a far-field propagation prediction based on near-field test results. The table shown in FIG. 7 shows a summary of results obtained with respect to the prototype of the antenna assembly 100 using a signal input reference power of 15 dBm. The values are the effective isotropic radiated power (EIRP) expressed in dBm as measured in one hemisphere of the electromagnetic field. These results indicate that the antenna assembly 100 can operate at least in frequency bands defined in the U.S., South America, and Europe as the LTE, GSM, CDMA, UMTS, and E-UTRA bands.

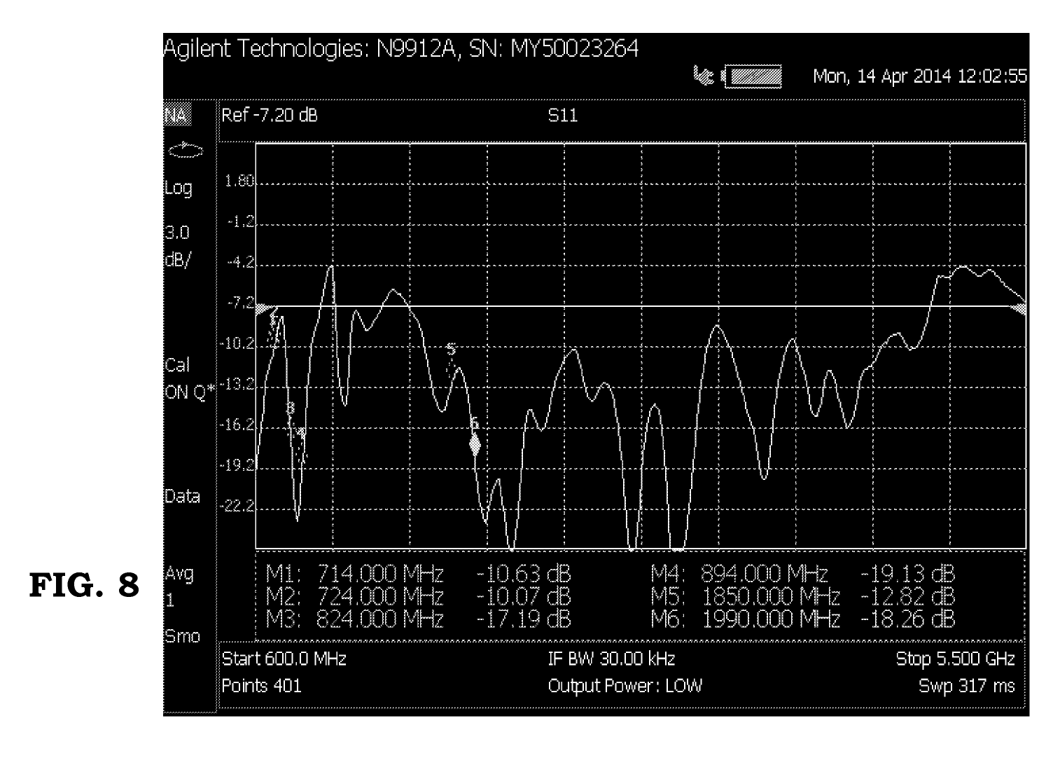

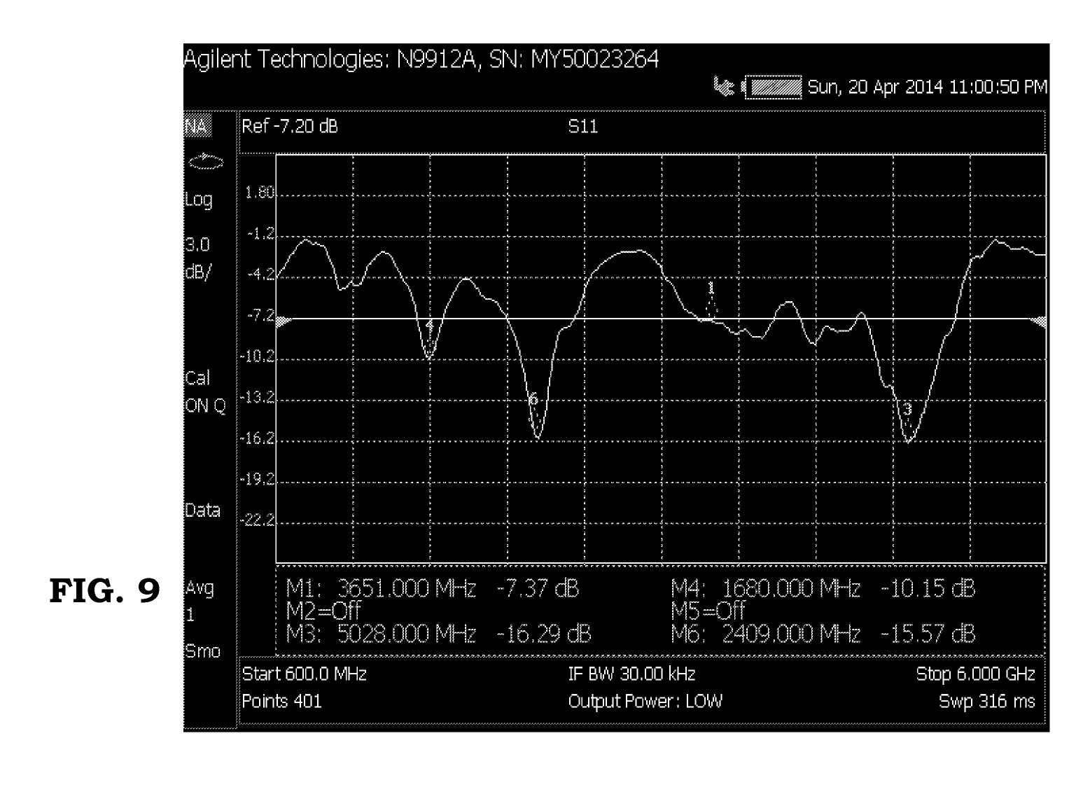

Tests were also applied to the antenna assembly 100 to measure return loss (S11), which is the amount of power reflected back at the antenna port of a network analyzer. The reflected energy can be used to determine the effectiveness of the impedance matching of the antenna. Lower measured values indicate better impedance matching. FIG. 8 shows the return loss (S11) of the first antenna structure 116 used for cellular band communication. FIG. 9 shows the return loss of the second antenna structure 118 used for wireless local area communication. The vertical reference line in FIGS. 8 and 9 includes a reference level of −7 dBm.

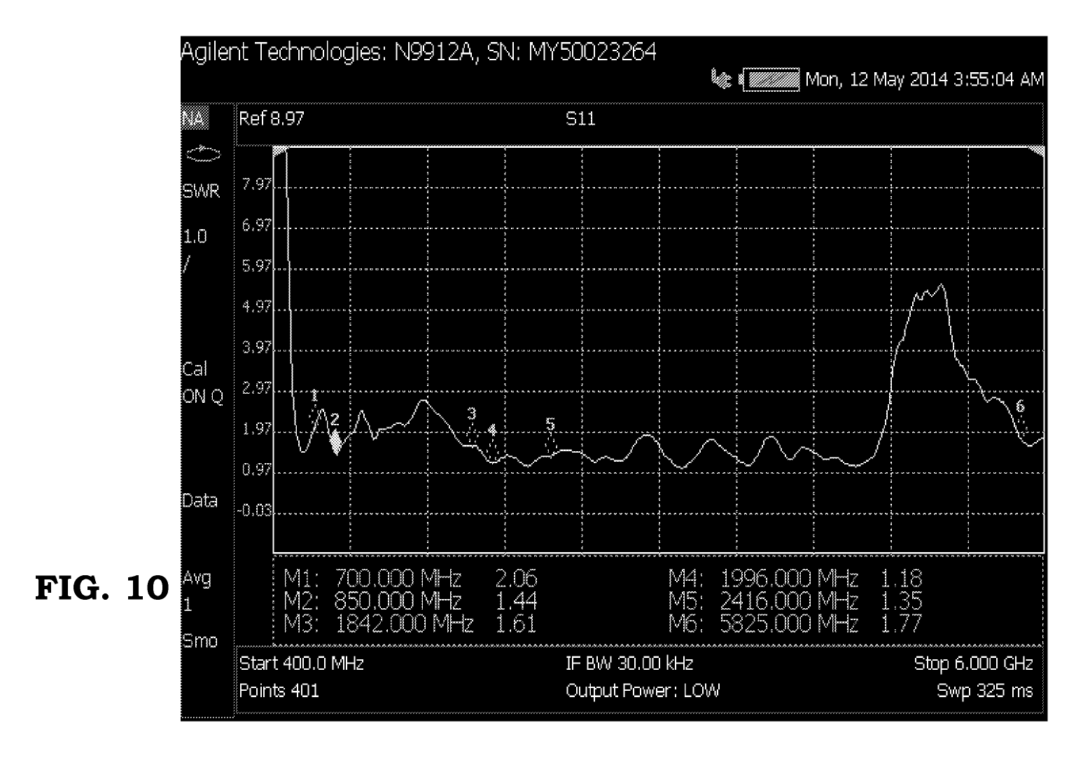

Impedance matching tests can also be run to obtain voltage standing wave ratio (VSWR) values. VSWR is the ratio of the peak amplitude of a standing wave to the minimum amplitude of the standing wave. Voltage is measured along a transmission line leading to one of the antenna structures 116, 118 of the antenna assembly 100. Smaller VSWR values indicate better impedance matching between the transmission line and the antenna structure 116 or 118. The ideal value of VSWR is 1.0, where there is no reflection. FIG. 10 shows the VSWR for the antenna assembly 100.

The antenna assembly 100 was also tested with regard to far-field characteristics. Tests were run to acquire data to measure the capability of the cellular communication antenna (i.e., the first antenna structure 116) of the antenna assembly 100 to transmit and receive in multiple directions, or angular orientations. A first test measured the omni-directional capabilities while the antenna assembly 100 was placed at a distance of 0.45 miles from a nearby cellular tower. A second test measured the omni-directional capabilities using a signal generator at 15 dBm and a distance of 30 feet from a log receiving antenna. The antenna assembly 100 was mounted on a cover with EFI potting material, a three D-cell battery pack, and a metal sleeve. This apparatus was placed on a shielded container filled with soil to simulate ground absorption effect at an origin point.

A receiving pattern observed the antenna assembly 100 positioned at various angles including 45°, 90°, 135°, 180°, 225°, 270°, 315°, and 360°. The frequency of the received signals included 700 MHz, 800 MHz, 1900 MHz, and a combination of frequencies. The receiving pattern ranged from about −57 dBm to about −44 dBm. Another receiving pattern test was run at 2100 MHz at the same angles and ranged from about −54 dBm to about −51 dBm. A transmitting pattern for the antenna assembly 100 was also observed using the same angles and frequencies. The transmitting pattern ranged from about −76 dBm to about −52 dBm.

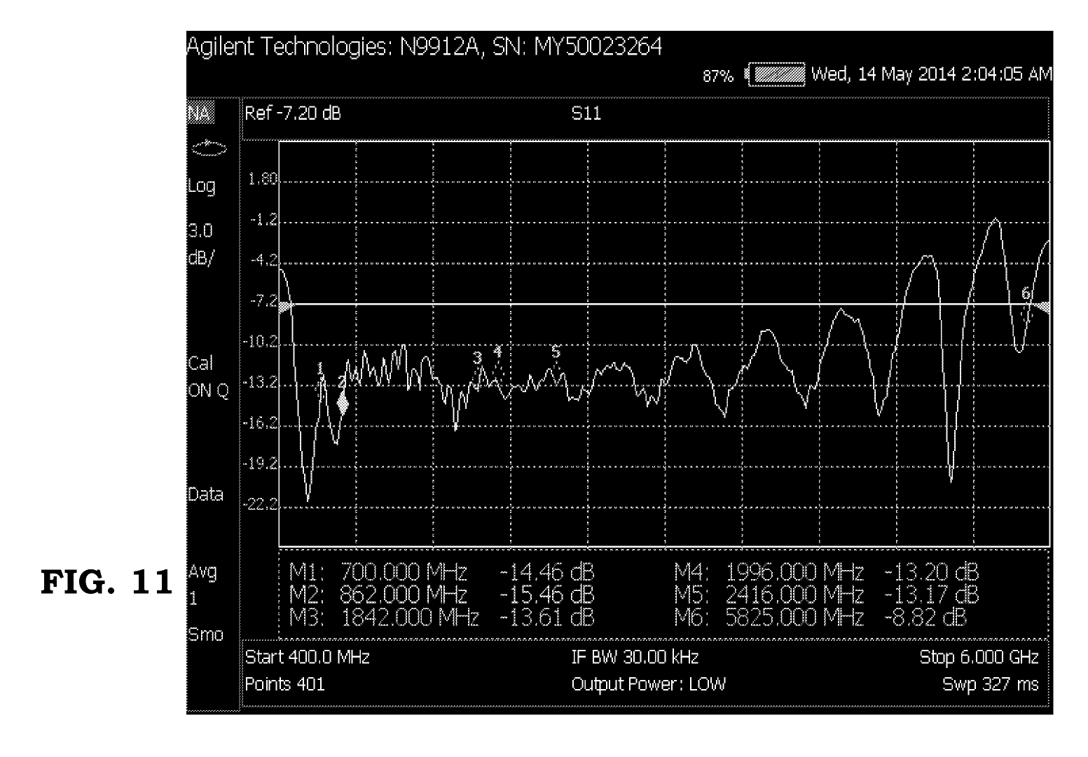

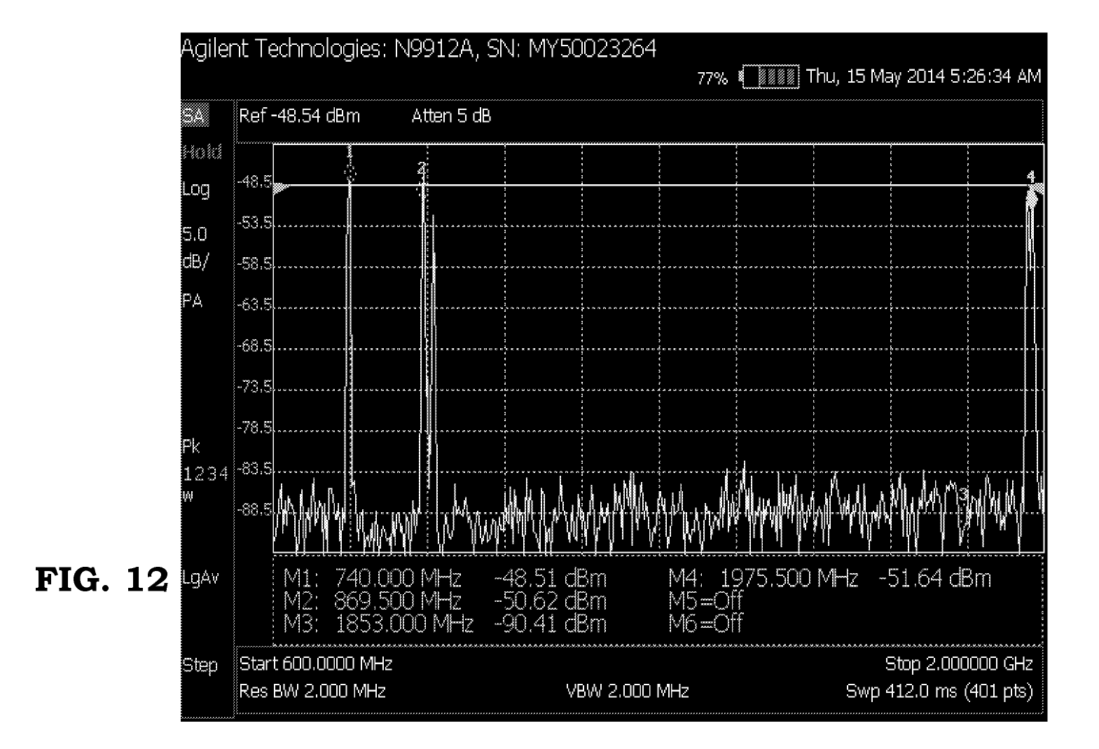

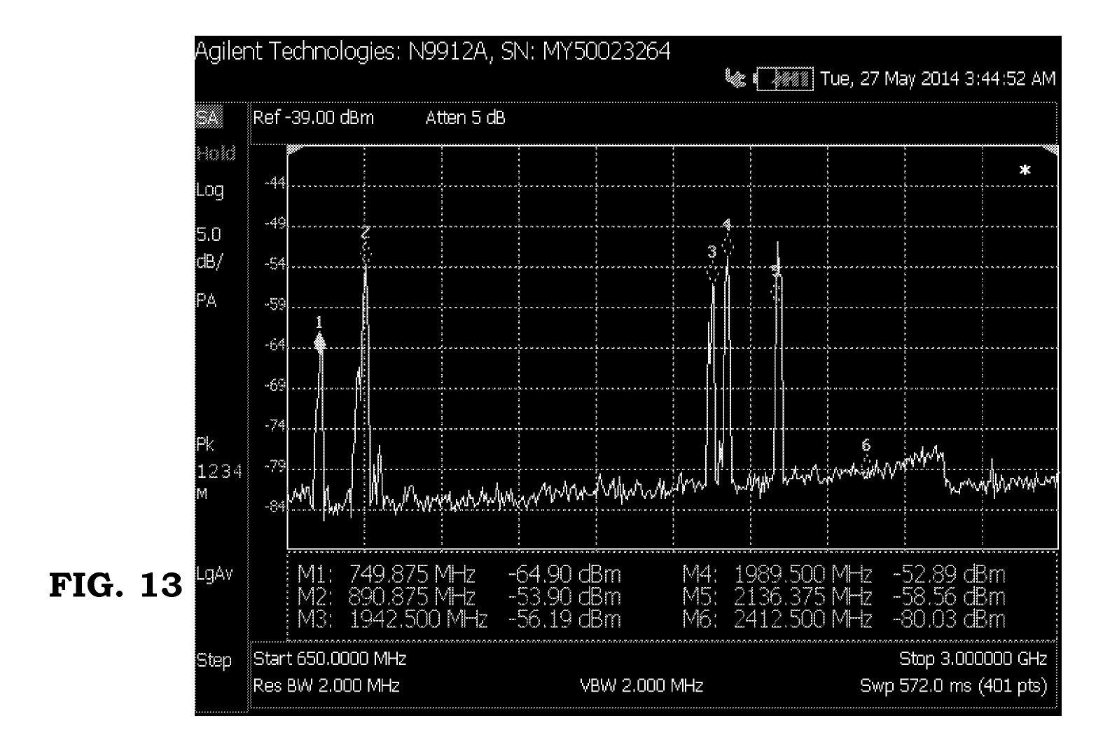

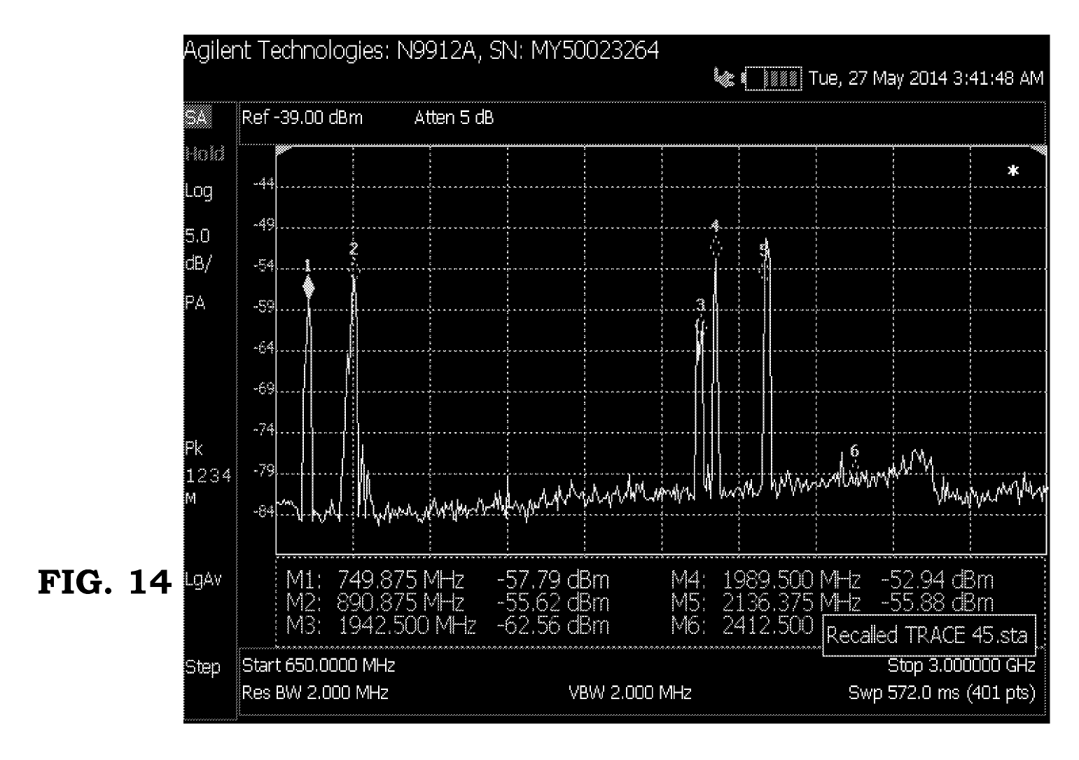

Additional far-field test traces were sampled. FIG. 11 shows the return loss (S11) values while the antenna assembly 100 was mounted on a test apparatus and including a battery pack. FIG. 12 shows a receiving pattern test with the antenna assembly 100 oriented at 45° with respect to a cell tower that is the signal source. FIG. 13 shows a receiving pattern of signals from a cell tower source with the antenna assembly 100 oriented at 180° and FIG. 14 shows a receiving pattern of signals from a cell tower source with the antenna assembly 100 oriented at 45°.

According to one implementation of the present disclosure, the antenna assembly 100 may simply include the printed circuit board 102, a cellular antenna structure (e.g., first antenna structure 116), and a wireless local area antenna structure (e.g., second antenna structure 118). The printed circuit board 102 may have a first surface (e.g., top surface 104) and a second surface (e.g., bottom surface 204). The cellular antenna structure may have a first section (e.g., first section 120) disposed on the first surface of the printed circuit board 102 and a second section (e.g., second section 220) disposed on the second surface of the printed circuit board 102. The wireless local area antenna structure may have a first section (e.g., first section 122) disposed on the first surface of the printed circuit board 102 and a second section (e.g., second section 222) disposed on the second surface of the printed circuit board 102.

In some embodiments, the antenna assembly 100 may further be configured such that the printed circuit board 102 includes the aperture 108 configured to accommodate the GPS module 350. The cellular antenna structure, wireless local area antenna structure, and GPS module 350 may be configured to operate simultaneously. The cellular antenna structure and wireless local area antenna structure may comprise copper traces and may be omni-directional antennas. The printed circuit board 102 may be substantially circular and have a diameter of less than five inches. In some embodiments, the printed circuit board 102 may be configured to be mounted in a water distribution system, such as in a fire hydrant of the water distribution system or in a below-ground-level valve cover of the water distribution system. In other embodiments, the printed circuit board 102 may be configured to be mounted on a vehicle.

The present disclosure also comprises describes a method of manufacturing an antenna assembly. According to various implementations, the method may include one step of fabricating a printed circuit board with a ground layer, a plurality of microstrip segments, and an aperture, wherein the microstrip segments form at least a first antenna and a second antenna. The method includes another step of installing a global positioning system (GPS) module in the aperture of the printed circuit board and coupling a terminal of the GPS module with the ground layer of the printed circuit board.

In some embodiments, the method of manufacturing the antenna assembly may be executed such that the step of fabricating the printed circuit board comprises forming the plurality of microstrip segments on a top surface and a bottom surface of the printed circuit board. Each of the first and second antennas may include microstrip segments on both the top surface and bottom surface of the printed circuit board. The first antenna may be configured to communicate in a cellular frequency band and the second antenna may be configured to communicate in a wireless local area frequency band.

The present disclosure can also be defined such that the printed circuit board simply comprises the first antenna structure, the second antenna structure, and the aperture. The first antenna structure may be configured to operate in a first microwave frequency band and the second antenna structure may be configured to operate in a second microwave frequency band. For example, the frequencies of the first and second microwave frequency bands may be separate. The aperture may be configured to accommodate the GPS module 350.

According to some embodiment, the printed circuit board may further comprise a ground layer configured to ground the GPS module and minimize interference with the first and second antenna structures. The first antenna structure may include a first section disposed on the first surface and a second section disposed on the second surface, and the second antenna structure may include a first section disposed on the first surface and a second section disposed on the second surface. The first antenna structure may operate in a cellular frequency band and the second antenna structure may operate in a wireless local area frequency band.

One should note that conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more particular embodiments or that one or more particular embodiments necessarily include logic for deciding, with or without user input or prompting, whether these features, elements and/or steps are included or are to be performed in any particular embodiment.

It should be emphasized that the above-described embodiments are merely possible examples of implementations, merely set forth for a clear understanding of the principles of the present disclosure. Any process descriptions or blocks in flow diagrams should be understood as representing modules, segments, or portions of code which include one or more executable instructions for implementing specific logical functions or steps in the process, and alternate implementations are included in which functions may not be included or executed at all, may be executed out of order from that shown or discussed, including substantially concurrently or in reverse order, depending on the functionality involved, as would be understood by those reasonably skilled in the art of the present disclosure. Many variations and modifications may be made to the above-described embodiment(s) without departing substantially from the spirit and principles of the present disclosure. Further, the scope of the present disclosure is intended to cover any and all combinations and sub-combinations of all elements, features, and aspects discussed above. All such modifications and variations are intended to be included herein within the scope of the present disclosure, and all possible claims to individual aspects or combinations of elements or steps are intended to be supported by the present disclosure.

1. An antenna assembly comprising:
a printed circuit board having a first surface and a second surface;
a cellular antenna structure having a first section disposed on the first surface of the printed circuit board and a second section disposed on the second surface of the printed circuit board; and
a wireless local area antenna structure having a first section disposed on the first surface of the printed circuit board and a second section disposed on the second surface of the printed circuit board.

2. The antenna assembly of claim 1, further comprising a global positioning system (GPS) module, wherein the printed circuit board comprises an aperture configured to accommodate the GPS module.

3. The antenna assembly of claim 2, wherein two or more of the cellular antenna structure, wireless local area antenna structure, and GPS module are configured to operate simultaneously.

4. The antenna assembly of claim 2, further comprising a ground plane formed on the second surface of the printed circuit board, the ground plane configured to provide a ground potential for the GPS module.

5. The antenna assembly of claim 1, wherein the cellular antenna structure is configured to operate within a frequency band ranging from 600 MHz to 6 GHz and the wireless local area antenna structure is configured to operate within a frequency band ranging from 2.0 GHz to 5.0 GHz.

6. The antenna assembly of claim 5, wherein a bandwidth of the cellular antenna structure is at least 400 MHz and a bandwidth of the wireless local area antenna structure is at least 200 MHz.

7. The antenna assembly of claim 1, wherein the cellular antenna structure and wireless local area antenna structure are configured as omni-directional antennas.

8. The antenna assembly of claim 1, wherein the cellular antenna structure and wireless local area antenna structure comprise copper traces.

9. The antenna assembly of claim 1, wherein the printed circuit board is configured to be mounted in a water distribution system.

10. The antenna assembly of claim 9, wherein the printed circuit board is configured to be mounted in a fire hydrant of the water distribution system.

11. The antenna assembly of claim 9, wherein the printed circuit board is configured to be mounted in a valve cover of the water distribution system, the valve cover located below ground level.

12. The antenna assembly of claim 1, wherein the printed circuit board is configured to be mounted on a vehicle.

13. The antenna assembly of claim 1, wherein the printed circuit board is substantially circular and has a diameter of less than five inches.

14. A method of manufacturing an antenna assembly, the method comprising the steps of:
fabricating a printed circuit board with a ground layer, a plurality of microstrip segments, and an aperture, the microstrip segments forming at least a first antenna and a second antenna;
installing a global positioning system (GPS) module in the aperture of the printed circuit board; and
coupling a terminal of the GPS module with the ground layer of the printed circuit board.

15. The method of claim 14, wherein the step of fabricating the printed circuit board comprises forming the plurality of microstrip segments on a top surface and a bottom surface of the printed circuit board.

16. The method of claim 15, wherein each of the first and second antennas includes microstrip segments on both the top surface and bottom surface of the printed circuit board.

17. The method of claim 14, wherein the first antenna is configured to communicate in a cellular frequency band and the second antenna is configured to communicate in a wireless local area frequency band.

18. A printed circuit board comprising:
a first antenna structure configured to operate in a radio frequency (RF) band;
a second antenna structure configured to operate in a microwave frequency band, wherein the frequencies of the RF band are different from the frequencies of the microwave frequency band; and
an aperture configured to accommodate a global positioning system (GPS) module.

19. The printed circuit board of claim 18, further comprising a ground layer configured to ground the GPS module and minimize interference with the first and second antenna structures.

20. The printed circuit board of claim 18, further comprising a first surface and a second surface, wherein the first antenna structure includes a first section disposed on the first surface and a second section disposed on the second surface, and wherein the second antenna structure includes a first section disposed on the first surface and a second section disposed on the second surface.

21. The printed circuit board of claim 18, wherein the first antenna structure operates in a cellular frequency band and the second antenna structure operates in a wireless local area frequency band.

22. The printed circuit board of claim 18, wherein the printed circuit board is substantially circular and has a diameter less than five inches.
